(19) United States
(12) Patent Application Publication
(10) Pub. No.: US 2025/0253833 A1
(43) Pub. Date: Aug. 7, 2025

(54) Latch with Separate Storage and Drive Path Circuitry and Methods

(71) Applicant: Arm Limited, Cambridge (GB)

(72) Inventor: Steve Dao, Austin, TX (US)

(21) Appl. No.: 18/430,547

(22) Filed: Feb. 1, 2024

(51) Int. Cl. H03K 3/037; H03K 19/20

(52) U.S. Cl. CPC H03K 3/0372; H03K 19/20

(57) ABSTRACT

According to one implementation, a circuit includes a latch comprising: drive path circuitry configured to transmit an output signal; and storage loop circuitry configured to retain the output signal. In one implementation, a circuit includes clock restructuring circuitry configured to generate respective first, second, and third clock inverter signals; a first latch configured to transmit a drive path signal; a second latch configured to transmit a storage loop signal; and a multiplexer, where: one or more transistor devices of the first and the second latches are activated by the second or the third inverter signals; the multiplexer is configured to select between the drive path signal and the storage loop signal based on a selector signal; and the selector signal is either a clock signal or the first clock inverter signal.

### I. FIELD

The present disclosure is generally related to methods and devices of latch with separate storage and drive path circuitry and methods.

### II. DESCRIPTION OF RELATED ART

This section is intended to provide information relevant to understanding various technologies described herein. As the section's heading implies, this is a discussion of related art that in no way implies that the discussion is prior art. Generally, related art may or may not be considered prior art. Any statement in this section should be read in this light, and not as admission of prior art.

Flip-flops are a type of fundamental memory circuit used in various central processing units (CPUs), graphic processing units (GPUs), or any other digital systems. The performance (e.g., the circuit delay) of the flip-flop may directly impact the performance of the CPU, GPU, and other digital systems. Accordingly, the reduction of flip-flop circuit delay is of utmost concern to improve overall performance. However, in current designs of flip-flops, reducing the delay associated within a slave latch of a respective flip-flop is difficult. Moreover, exacerbating the problem, the presence of a storage feedback loop in the slave latch can add considerable parasitic delay to an overall delay of the slave latch. Further, as the storage feedback loop is required, it cannot be easily removed to alleviate such parasitic burden. Hence, there exists a need in the art for a more efficient flip-flop design that seeks to reduce inefficiencies, improve integration schemes, and enhance speed and performance.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1A is a block diagram of an example circuit in accordance with various implementations described herein.

FIG. 1B is a block diagram of an example circuit in accordance with various implementations described herein.

FIG. 2A is a schematic diagram of an example circuit in accordance with various implementations described herein.

FIG. 2B is a schematic diagram of an example circuit in accordance with various implementations described herein.

FIG. 2C is a schematic diagram of an example circuit in accordance with various implementations described herein.

FIG. 2D is a schematic diagram of an example circuit in accordance with various implementations described herein.

FIG. 3 is a schematic diagram of an example circuit in accordance with various implementations described herein.

FIG. 4 is a schematic diagram of an example circuit in accordance with various implementations described herein.

FIG. 5 is a schematic diagram of an example circuit in accordance with various implementations described herein.

FIG. 6A is a diagram of an example circuit layout in accordance with various implementations described herein.

FIG. 6B is a diagram of an example circuit layout in accordance with various implementations described herein.

FIG. 7 is an operational method in accordance with various implementations described herein.

FIG. 8 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

According to one implementation of the present disclosure, a circuit includes a latch comprising: a drive path circuitry configured to transmit an output signal; and a storage loop circuitry configured to retain the output signal.

According to one implementation of the present disclosure, a circuit includes a first latch; and a second latch comprising multiplexer circuitry configured to select between a first input signal and a second input signal.

According to one implementation, a method comprises: in response to a first phase of a clock signal, receiving, at a first latch, a data input signal; and in response to a second phase of the clock signal: receiving, at a drive path circuitry of the second latch, the input signal from the first latch; and transmitting the input signal from the drive path circuitry of the second latch, where the drive path circuitry is distinct from a storage path circuitry of the second latch.

According to one implementation, a circuit includes clock restructuring circuitry configured to generate respective first, second, and third clock inverter signals; a first latch configured to transmit a drive path signal; a second latch configured to transmit a storage loop signal; and a multiplexer, where: one or more transistor devices of the first and the second latches are activated by the second or the third inverter signals; the multiplexer is configured to select between the drive path signal and the storage loop signal based on a selector signal; and the selector signal is either a clock signal or the first clock inverter signal.

In certain designs, a flip-flop may include two “back-to-back” latches called a master first latch followed by a slave second latch. In various implementations, the performance of the flip-flop can depend on two criteria: 1) a set-up time corresponding to a delay of the master latch, and 2) a “clock input-to-Q output” (i.e., C2Q) time corresponding to a delay of the slave latch. While, in certain cases, the set-up time can normally be improved by delaying a clock signal into the flip-flop, the C2Q time would require innovative circuit design to reduce the C2Q delay.

Schemes and techniques of the present invention allow for a split of a storage feedback loop into a parallel path that is physically distinct from an active drive path. Advantageously, the separation of a slave latch into two bifurcated parallel paths where a first path is the storage feedback loop and a second path is the main output drive path effectively allows for the inherent parasitic load to be removed from the C2Q delay. In addition, according to various inventive aspects, a multiplexer may combine both paths to generate a main output signal of the slave latch or the flip-flop. Notably, such inventive aspects provide minimal intrusion and an overall 45% improvement in flip-flop performance as observed across process, voltage, and temperature (PVT).

Certain definitions have been provided herein for reference. A “pass gate” corresponds to a pass-transistor logic including a p-channel field-effect transistor (PFET) device and an n-channel field-effect transistor (NFET) device configured to operate as a switch. An “inverter” corresponds to a coupled PFET transistor and an NFET transistor device coupled so as invert an input signal as an inverted output signal.

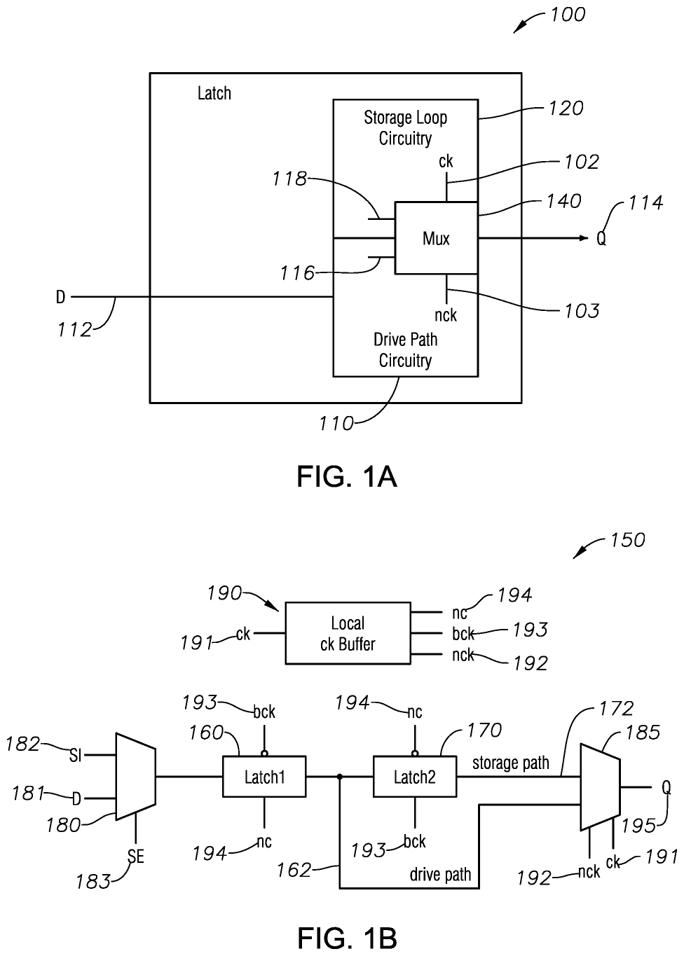

Referring to FIG. 1A, a block diagram of an example latch 100 is shown. In various implementations, the latch 100 may be a semiconductor-based single-latch circuit structure having at least one transistor-based memory element to store a particular state. In some implementations, the latch 100 may be an improved “slave” latch circuitry of a master-slave flip-flop circuit. As illustrated, the latch 100 can include a drive path circuitry 110 and a storage loop circuitry 120, where certain portions of both the drive path circuitry 110 and the storage loop circuitry 120 may be combined and configured as a multiplexer 140.

In certain implementations, the drive path circuitry 110 is the circuitry configured to transmit an output signal (i.e., drive path signal; Q output 114). Specifically, as one example, the drive path circuitry is the circuitry of the latch 100 responsible for the transitioning of the Q output 114 when a D input 112 has transitioned. In an example operation, such a transitioning of the Q output 114 occurs from a clock transition from a first level (e.g., a digital “0”; “low”) to a second level (e.g., a digital “1”; “high”).

In certain implementations, the storage loop (path) circuitry 120 is the circuitry configured to retain the output signal (e.g., storage loop signal, Q output 114). Specifically, as one example, such a retention of the storage loop signal occurs from a clock transition (of an example clock signal 102 (i.e., ck signal) or an example first clock inverter signal 103 (i.e., nck signal) (i.e., a first inverted or delayed version of the ck signal) from the second level (e.g., a digital “1”, “high”) to the first level (e.g., a digital “0”, “low”), as well as the duration of time the example clock signal 102 (or first clock inverter signal 103) stays at the first level. As may be appreciated, the storage loop circuitry 120 of the latch 100 is fully distinct from drive path circuitry 110 and uninvolved with the transitioning of the Q output 114.

As illustrated, in various implementations, distinct portions of each of the drive path circuitry 110 and the storage loop circuitry 120 can be combined and configured as a multiplexer 140. In various cases, as the selector, the clock signal 102 can select between two inputs of the multiplexer 140:1) the drive path signal 116 from the drive path circuitry 110; and 2) the storage path signal 118 from the storage loop circuitry 120, and output a multiplexer output signal, Q output 114. For instance, when the clock signal 102 is at the second level (e.g., a digital “1”, “high”), the multiplexer would choose the drive signal 116, and when the clock signal (e.g., ck signal 102, nck signal 103) is at the first level (e.g., a digital “0”, “low”), the multiplexer would choose the storage loop signal 118.

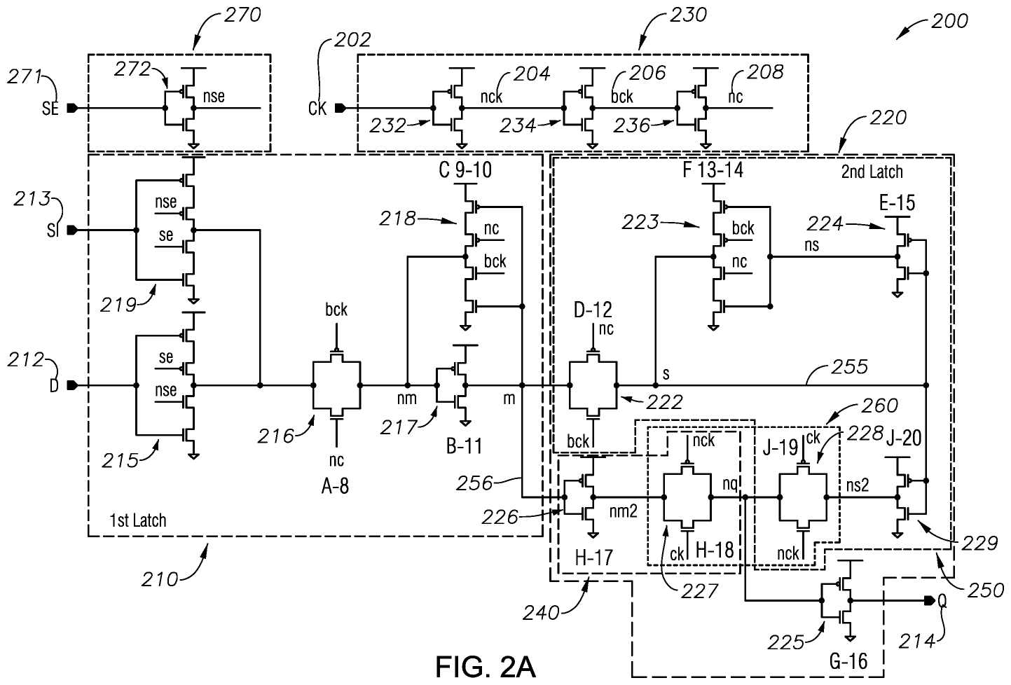

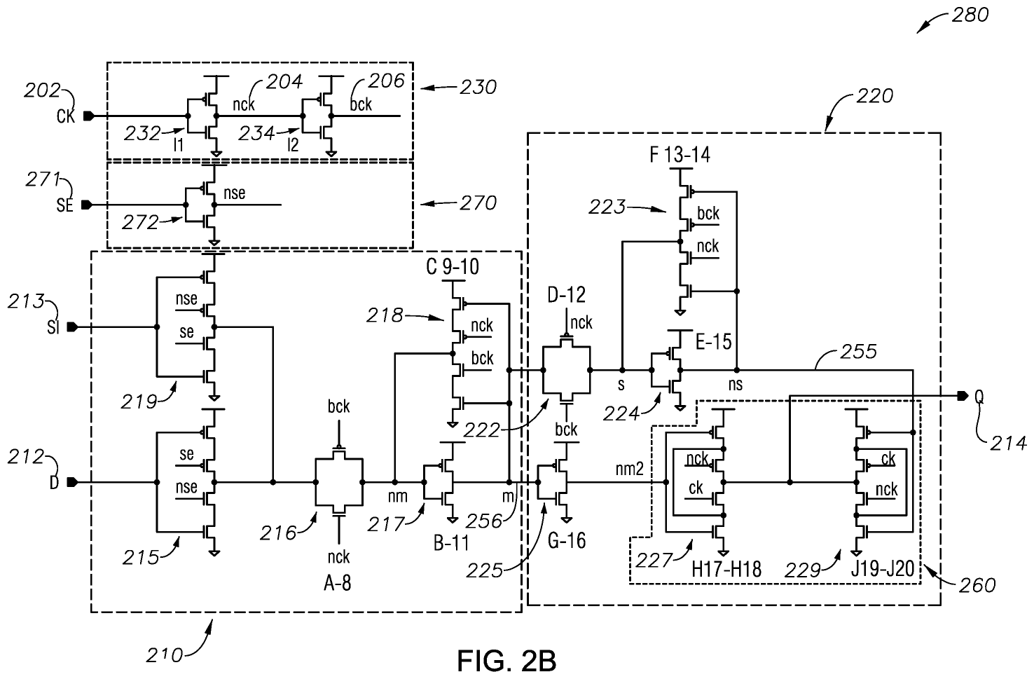

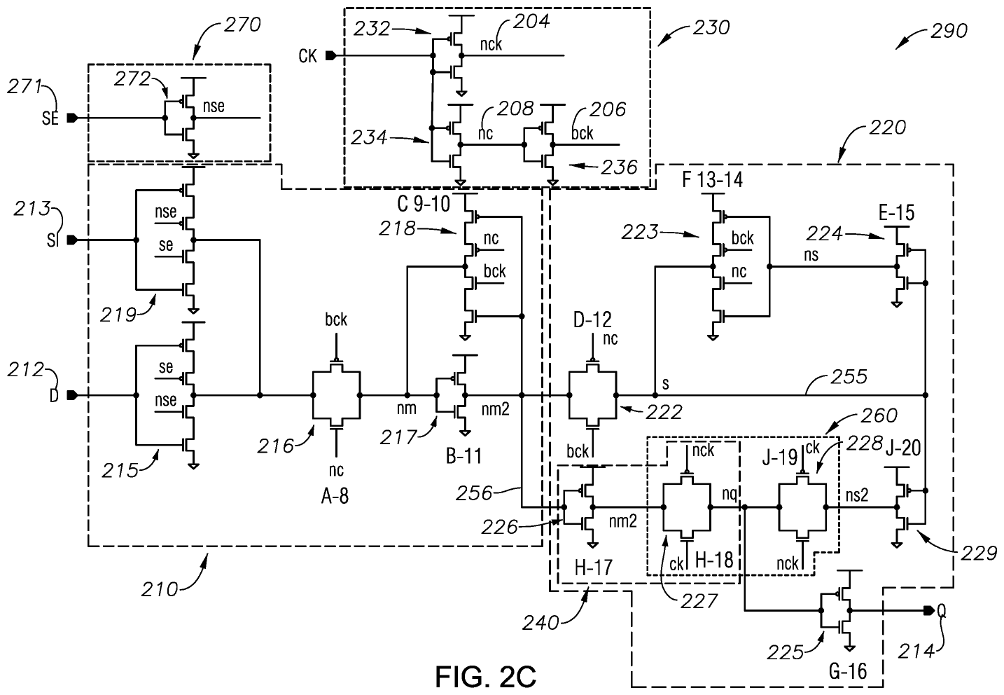

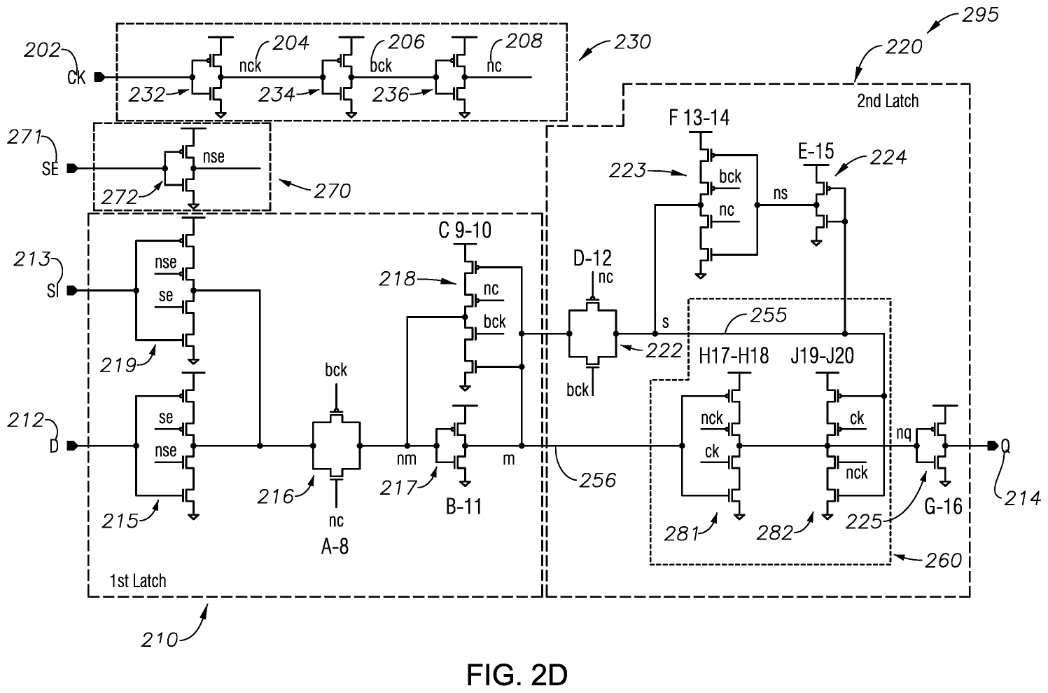

In one implementation, the storage loop circuitry 130 can include a storage node, where the storage node comprises a respective feedback loop memory structure (e.g., as illustrated in the storage loop circuitry 250 of the second latch 220 in FIG. 2A). Also, in such an implementation, the drive path circuitry 140 would be configured and designed as wholly independent (i.e., distinct) from the storage node. Advantageously, such an implementation allows for a complete storage node by-pass of the drive signal 116. Hence, the drive path signal 116 can be separated from the storage loop circuitry and the storage loop signal 118. Advantageously, by doing so, the drive path signal 116 would be “unburdened” with parasitic and additional load; and hence, the C2Q speed increase and delay reduction benefit can be realized.

Referring to FIG. 1B, a block diagram of an example dual latch (i.e., “master-slave” latch, flip-flop, circuit) 150 is shown. As illustrated, the example circuit 150 may be a scan-enable flip-flop implementation. In certain implementations, the circuit 150 can include a first latch 160 (i.e., latch 1, a master latch) and a second latch 170 (i.e., latch 2, a slave latch), clock construction circuitry 190 (i.e., clock-restructuring circuitry) (e.g., a local clock buffer), and scan-enable (SE) circuitry 180. As shown, the local clock buffer 190 is configured to receive a clock signal (ck) 191 and transmit first, second, and third clock inverter signals (e.g., respective first, second, and third delayed versions of the clock signal 191) (e.g., nck signal 192, bck signal 193, and nc signal 194). Also, the scan-enable (SE) circuitry 180 is configured to transmit a scan enable (SE) control signal 183 to enable or disable the circuit 150 via either a functional input (D input) 181 or a test input (SI input) 182. In such an implementation, when enabled (e.g., D input), and in response to the bck and/or the nc signals 193, 194 activating one or more transistor devices of the master latch 160 and the slave latch 170, the master latch 160 is configured to output a drive path signal along a drive path 162, while the slave latch 170 is configured to output a storage loop signal along a storage path 172. In addition, at the multiplexer 185, one of the nck signal 192 or the clock signal (ck) 191 can be configured to select between the drive path signal and the storage loop signal, and output a multiplexed output signal 195. Advantageously, according to the inventive aspects (as described herein), by utilizing different clock signals in the activation of the first and second latches 160 and 170 in comparison to clock signals utilized in the selection performed by the multiplexer 185, a significant reduction in C2Q delay may be realized. In various other implementations (not shown), the clock construction circuitry 190 can include an N number of clock inverters (i.e., clock gates), where configuration of such circuitry can be of split-parallel clock inverters or serial-clock inverters.

Referring to FIG. 2A, a circuit diagram of an example dual latch (i.e., “master-slave” latch, flip-flop, circuit) 200 is shown. As illustrated, the example circuit 200 may be a scan-enable three serial-clock inverter flip-flop implementation. In certain implementations, the circuit 200 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. As may be appreciated, in certain implementations, the second latch 220 can correspond to the latch 100 of FIG. 1A.

As shown, in certain cases, the first latch (i.e., master latch) 210 can include at least blocks (i.e., circuit elements): A-8, B-11, and C9-10. (For the reader's convenience, in addition to reference numerals, various circuit elements have been denoted alpha-numerically). The blocks of the first latch 210 can include: a pass-gate A-8 216; an inverter B-11 217 (including a PFET transistor and an NFET transistor); tri-state inverter C9-10 218 (including two PFETs and two NFETs); and respective tri-state devices 219, 215 configured to receive a functional input (i.e., D input) 212 and a test input (i.e., SI input) 213. As illustrated in FIG. 2A, in some implementations, as a scan flip-flop, the circuit 200 may utilize the scan enable circuitry 270 to transmit a scan enable (SE) control signal 271 to enable or disable the circuit 200 via either the functional input (D input) 212 or the test input (SI input) 213 in the first latch 210.

As shown, in some cases, the second latch (i.e. slave latch) 220 can include at least blocks (i.e., circuit elements): D-12, F13-14, E-15, G-16, H-17, H-18, J-19, and J-20. (For the reader's convenience, in addition to reference numerals, various circuit elements have been denoted alpha-numerically). The blocks of the second latch 220 can include: a pass gate D-12 222 (i.e., pass-transistor logic) (including a PFET and an NFET transistor); a tristate inverter F13-14, 223 (including two PFETs and two NFETs); an inverter E-15 224; an inverter G-16 225 (e.g., an output buffer); an inverter H-17 226, a pass gate H-18 227 (i.e., pass-transistor logic) (including a PFET and an NFET transistor); a pass gate J-19 228 (i.e., pass-transistor logic) (including a PFET and an NFET transistor); and an inverter J-20 229.

In one implementation, as shown, the drive path circuitry 240 may include: the inverter H-17 226 and the pass gate H-18 227. As may be appreciated, in such an example, the inverter G-16 225 may be configured as an output buffer (e.g., independent from the drive path circuitry 240). Also, in such an implementation, the storage loop circuitry 250 may include: the pass-gate D-12 222; the tristate inverter F13-14 223; the inverter E-15 224; the pass gate J-19 228 (i.e., pass-transistor logic) (including a PFET and an NFET transistor); and the inverter J-20 229. Moreover, in such an implementation, as one example, the pass gate H-18 227 (of the drive path circuitry 240) and the pass gate J-19 228 (of the storage loop circuitry 250) may be configured as a multiplexer 260 (i.e., multiplexer circuitry). As may be appreciated, a clock signal (e.g., nck signal) may be configured as the selector of the multiplexer 260 to select between a drive path signal (of the drive path circuitry 240) and a storage loop path signal (of the storage loop circuitry 250) and transmit a multiplexed output signal, Q output 214. In contrast, in another implementation, the inverter G-16 225 may be configured as part of the drive path circuitry (e.g., as shown in FIG. 2B). Also, in a second implementation, the multiplexer 260 (i.e., multiplexer circuitry) may include both the inverters H-17 226 and J-20 229 in addition to the pass gates H-18 227 and J-19 228. Moreover, in a third implementation, the multiplexer 260 (i.e., multiplexer circuitry) may include: the inverters H-17 226 and J-20 229, the pass gates H-18 227 and J-19 228, as well as the inverter G-16 225.

Similar to FIG. 1A, in certain cases, the drive path circuitry 240 is the circuitry of the circuit 200 responsible for the transitioning of the Q output 214 when the D input 212 has transitioned. In an example operation, such a transitioning of the Q output 214 occurs from a clock transition from a first level (e.g., a digital “0”; “low”) to a second level (e.g., a digital “1”; “high”). In addition, the storage loop (path) circuitry 250 is the circuitry configured to retain the output signal 214 (e.g., storage loop signal, Q output 214). Specifically, as one example, such a retention of the storage loop signal occurs from a clock transition from the second level (e.g., a digital “1”, “high”) to the first level (e.g., a digital “0”, “low”), as well as the duration of time as a clock signal (e.g., nck signal, a delayed and inverted version of the ck signal 202) stays at the second level. As may be appreciated, the storage loop circuitry 250 of the second latch 220 would be fully distinct from the drive path circuitry 240, and would be uninvolved with the transitioning of the Q output 214.

Advantageously, in FIG. 2A, the pass-gate H-18 227 of the second latch 220 (i.e., slave latch) may be positioned as either adjacent to (e.g., directly coupled to) or would in fact be the circuitry configured for the generation and transmission of the Q output signal 214. Accordingly, in certain inventive aspects, the storage loop circuit path (for signal transmission through the storage loop circuitry 250) can include two pass gates (e.g., pass gate D-12 222, pass gate J-19 228) and the drive path (for a signal transmission through the drive path circuitry) would include one pass gate (e.g., pass gate H-18 227).

As illustrated in FIG. 2A, the clock construction (i.e., clock-restructuring) circuitry 230 (i.e., clock network) would implement a serial clock operation for the first and second latches 210, 220. In one implementation, the clock signal construction circuitry 230 may be realized by a single serial path including a main clock signal 202 (i.e., clock signal, ck signal) and first, second, and third clock inverters 232, 234, 236 (i.e., first, second, and third clock gates, where each of the clock gates include a first and a second transistor (e.g., a PFET and a NFET)) coupled serially and configured to generate first, second, and third delayed versions of the clock signal: nck signal 204, bck signal 206, and nc signal 208, respectively (i.e., first, second, and third clock inverter signals)).

In terms of polarity, the nc signal 208 would be the same as the nck signal 204, but just with additional delay. Such an additionally delayed signal, advantageously, would benefit the speed of “setup time” by the use of the nc signal 208 to “drive” various locations of the circuit 200. Accordingly, in such an implementation, with the exception of the multiplexer circuitry 260 (i.e., H-18 and J-19 pass gates) that is driven by the nck signal 204, the nc signal 208 can be configured to drive, for example, one or more of at least: an NFET of the transistor A-8 216, a PFET of the tri-state inverter C9-10 218, a PFET of the inverter D-12 222, and an NFET of the tri-state inverter F13-14 223. Accordingly, by doing so, the nck signal 204 would be “least loaded” (e.g., the least quantity of transistors that receive the signal) as possible, and would transition “faster” and “sharper” in comparison to the nc signal 208.

In such an example, while the nc signal 208 would be “slower”, because it's configured to drive non-critical signals, the slowness of its transition would be immaterial. In contrast, the nck signal 204 is configured to drive the most critical signal, the PFET of the pass gate H-18 227. Hence, a greater a load that is placed on the nck signal 204, the “slower” the nck signal 204 would become. For instance, the PFET of the pass gate H-18 227 would turn “on” slower and that would impact the C2Q falling edge.

Specifically, in one example, as the primary driver when, e.g., the node nm2 is at an operating voltage, VDD, the circuit 200 would rely on the PFET of the pass gate H-18 227 to also pull, e.g., the node, nq, to VDD as well. In doing so, the Q-output would transition to ground, VSS, faster. Thus, a C2Q falling edge is shown to be heavily impacted by the load on the nck signal 204. Hence, the lesser the load on the nck signal 204, the quicker the PFET of the H-18 227 device would turn “on”, and the faster the C2Q fall would be. In such a manner, the goal would be to make the C2Q fall to be as close to the C2Q rise as possible.

Advantageously, as shown in FIG. 2A, the nck signal 204 is received by just four transistors (e.g., PFET of the pass gate H-18 227; NFET of the pass gate J-19 228; and the PFET and NFET of the second clock inverter 234)) (e.g., in comparison to the implementation in FIG. 2B where the nck signal 204 is received by eight transistors (i.e., has eight gate-loads)). Advantageously, for example, the reduced delay by “cutting the load in half” (i.e., reducing the gate-load from eight to four) would be at least approximately equivalent to a delay in turning “on” the PFET of the pass-gate H-18 227.

In an example, the “parasitics” of a storage node would be “sitting” (present) on a pass-gate, such as the pass-gate D-12 222 of the second latch 220 (i.e., slave latch, slave stage). Accordingly, in an example operation, when, e.g., a clock signal goes “high, and transitions from a digital “0” to a digital “1”, the two diverging circuit paths can be bifurcated at node “m”, which is the input to the slave stage 220. Correspondingly, an input signal (e.g., D-input 212) will be bifurcated into a storage path 255 (e.g., the middle, non-critical path) and into a drive path 256 (e.g., the lower path, strictly the two transistor gates going into an output buffer G-16 225). Advantageously, when a setup condition is met, most of the delay may be confined to a separate, parallel, non-critical path, while a separate fast critical path may flow directly to the output through a drive circuitry (e.g., once a clock signal goes “high”).

In addition, the inclusion of pass gate J-19 228 of the multiplexer 260 is also important in order to “hold” the nq node (e.g., the two pass gates H-18, J-19 of the multiplexer) at a stable state, and prevent the voltage at the nq node from “floating”. For instance, this may occur when a clock signal goes back from a digital “1” to a digital “0”. Accordingly, pass gate H18 would turn off, and so without the pass gate, J-19 228, a floating node would occur. Hence, the pass gate J-19 228 would turn on in order to keep the nq node at what was set by the pass gate H-18 when clock was at a digital “1”. Moreover, in operation, when the clock signal goes to a digital “1”, the pass gate D-12 222, similarly, would turn “on” (e.g., like the pass gate H-18 227). However, even though a delay signal would propagate between the pass gate D-12 222 and the inverter J-20 228, such a scenario would be of minimal concern because there would be an entire half-cycle delay interval for propagation. Hence, the primary concern for optimization would be to have a fast path once the clock signal goes to a “high” state in order to transition the output correctly as fast as possible.

In an example operation, initially, in response to a first phase of a clock signal 202 (e.g., a first clock phase, ck=0), an input signal (e.g., D input signal 212 or SI signal 213) is received and stored at a storage loop/storage node (e.g., tristate inverter C9-10 and inverter B-11) of a first latch 210. Next, in response to a second phase of the clock signal 202 (e.g., a second clock phase, ck=1, nck=0, bck=1, nc=0) the stored input signal (e.g., 212, 213) from the storage loop of the first latch 210 is received to the drive path circuitry 240 of the second latch 220. Correspondingly, the input signal (e.g., 212, 213) may be transmitted through the drive path circuitry 240, and output through the multiplexer 260, as the Q output signal 214. Moreover, in a subsequent step, in response to the first phase of the clock signal 202 (e.g., the first clock phase, ck=0), the stored (prior data) input signal (i.e., Q output of a current state) may be “held” (i.e., stored) at the at the storage path circuitry 250 of the second latch 220 (i.e., the slave latch). For example, specifically, the stored input signal can be stored at a storage loop/storage node (e.g., tristate inverter F13-14 and inverter E-15) of the second latch 220. In this manner, the storage loop circuitry 250 (e.g., specifically the pass gate J-19) and the drive path circuitry 240 (specifically the pass gate H-18) are configured to operate out-of-phase, where the out-of-phase operation comprises opposing activation of the storage loop circuitry 250 and the drive path circuitry 240.

Also, in a subsequent step, in response to a second occurrence of the first phase of the clock signal 202 (e.g., the first clock phase, ck=0), the stored (prior data) input signal (i.e., Q output of a new current state) may be “held” (i.e., stored) at the storage path circuitry 250 of the second latch 220 (i.e., the slave latch). For example, specifically, the stored input signal can be stored at a storage loop (e.g., tristate inverter F13-14) of the second latch 220.

In certain implementations, the first and second latches 210, 220 include respective first and second storage nodes, where each of the first and second storage nodes comprises a respective feedback loop memory structure (e.g., inverter B-11 and tri-state inverter C9-10; and inverter E-15 and tri-state inverter F13-14), where the feedback loop memory structure comprises an inverter (e.g., inverter B-11, inverter E-15) and a tri-state inverter (e.g., tri-state inverter C9-10, F13-14). Also, in such implementations, the drive path circuitry 240 is configured and designed as wholly independent (i.e., distinct) from such first and second storage nodes. Advantageously, such implementation, allow for complete storage node by-pass of the drive signal.

Advantageously, in terms of overall delay benefit, in inventive aspects, approximately 60% may be derived from the inventive bifurcated circuit paths, while the remaining approximately 40% would be realized due to judicious restructuring of the clock internal signals within the circuit. Advantageously, such inventive flip-flops (as described herein) allow for a C2Q delay improvement of approximately 30-40% in comparison to known standard flip-flops that do not envision the inventive bifurcation of the drive path and storage loop (path) signals.

Referring to FIG. 2B, a circuit diagram of an example dual latch (i.e., “master-slave” latch, flip-flop, circuit) 280 is shown. As illustrated, the example circuit 280 may be a scan-enable two serial-clock inverter flip-flop implementation. In certain implementations, the circuit 280 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. In various implementations, the second latch 220 in FIG. 2C can correspond to the latch 100 and the second latch 220 of FIGS. 1A and 2A.

As illustrated, the circuit 280 (in FIG. 2B) can include the same elements and would be configured for the same operations as the circuit 200 (in FIG. 2A). However, the circuit 280 includes two notable distinctions. First, the clock reconstruction circuitry 230 includes just a main clock signal 202 (i.e., clock signal, ck signal) and first and second clock inverters 232, 234 (i.e., first and second clock gates, where both of the clock inverters include a first and a second transistor (e.g., a PFET and a NFET)) coupled serially and configured to generate first and second delayed versions of the clock signal: nck signal 204 and bck signal 206, respectively (i.e., first and second clock inverter signals). Accordingly, in the implementation as shown in FIG. 2B, there would be no separate nc signal (as in FIG. 2A). Hence, in such an implementation, the nck signal would be loaded at each of the various transistor inputs as shown. Second, in such an implementation, as shown in FIG. 2B, the inverter G-16 225 has been moved to a different location now coupling between the first latch 210 and the inverter H-17 and pass gate H-18 227. As may be appreciated, the inverter H-17 and pass gate H-18 227 in FIG. 2B are the exact same circuitry configuration as in FIG. 2A, just shown differently. Notably, by moving the inverter G-16 225, this implementation would not include a buffered output.

Referring to FIG. 2C, a circuit diagram of an example dual latch (i.e., “master-slave” latch, flip-flop, circuit) 290 is shown. As illustrated, the example circuit 290 may be a scan-enable parallel inverter flip-flop implementation. In certain implementations, the circuit 290 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. In various implementations, the second latch 220 in FIG. 2C can correspond to the latch 100 and the second latch 220 of FIGS. 1A and 2A.

As shown, the circuit 290 in FIG. 2C can include the same elements and would be configured for the same operations as the circuit 200 in FIG. 2A. However, instead of the serial clock implementation in FIG. 2A, the circuit 290 illustrates a parallel path/split-clock implementation. For example, the clock restructuring circuitry 230 would include two parallel paths both configured to receive a main clock signal 202 (i.e., ck signal; a clock signal); a first clock path can include two clock gates (i.e., clock inverters 234 and 236) coupled in series, and a second clock path with one sole clock gate (i.e., clock inverter 232).

Notably, on the first clock path, the clock signal 202 is transmitted through a first clock gate 234 (i.e., a first clock inverter), and is output as a first delayed version of the clock signal, nc signal 208 (i.e., a first clock inverter signal). The nc signal 208 is then transmitted through a second clock gate 236 (i.e., a second clock inverter) that is output as a second delayed version of the clock signal 202, bck signal 206 (e.g., a second clock inverter signal). In addition, on the second clock path, in parallel with the first clock path, the clock signal 202 is transmitted through a third clock gate 232 (i.e., a third clock inverter), and is output as a third delayed version of the clock signal 202, nck signal 204 (i.e., a third clock inverter signal). As may be appreciated, while distinct from one another, in this implementation, the nck signal 204 (i.e., the third clock inverter signal) and the nc signal 208 (i.e., the first clock inverter signal) are the same signal with the same polarity, as they each are derived from the same input.

Advantageously, in such an implementation, and in contrast to the nck signal 204 in FIG. 2B, the nck signal 204 in FIG. 2C is configured to not drive any clock gates. By doing so, the nck signal 204 would be configured to drive just the pass-gates of the multiplexer 260 (e.g., driving just one PFET and one NFET loads). Accordingly, the nck signal 204, in such a dedicated inverter implementation (i.e., the sole third inverter), would be “unburdened” by any extraneous loads. Hence, as an advantage in operation, the circuit 290 would provide falling edges of clock signals that are both “equalized” and operate approximately as fast as rising edges of the clock signals.

In contrast to FIG. 2C, in FIG. 2B, because the nck signal 204 drives the second clock gate 234 to generate the bck signal 206, and because the nck signal is “being loaded” (e.g., providing an input signal) at several distinct transistor devices (e.g., 8 devices for the nck signal) of the circuit 280, the PFET of the pass-gate H-18 227 would turn “on” slower (due to the additional loading) and also add “imbalance” to the delay.

To explain in greater detail, in example circuit operations, when a clock signal goes from a digital “0” to a digital “1”, the node nm2 (e.g., as shown between inverter G-16 225 and the inverter and pass gate combination H-17, H-18 227 in FIG. 2B; and between the inverter H-17 226 and pass gate H-18 in FIG. 2C) has a “0” polarity (e.g., at ground), and so, at the pass gate H-18, the NFET of the pass gate H-18 would primarily drive the “0” (e.g., also, because the PFET of the pass gate H-18 would relatively not be utilized for such driving, it may still operate “fast”), and the output Q would be a digital “1”.

On the other hand, when the node nm2 is a digital “1”, the example circuits (e.g., as illustrated in FIGS. 2A and 2C) would mostly rely on the PFET of the pass-gate H-18 227 to drive the digital “1”, as the NFET would not be “very strong”. Also, the PFET would have at least have a one inverter delay to turn “on”; so hence, the faster the PFET can be turned “on”, the faster the nq node can go to a digital “1”, and the Q output can go to a digital “0”.

Thus, for example in FIG. 2B, where the PFET of the pass-gate H-18 227 is driven by a “loaded” clock signal (e.g., due to 8 devices transistor devices receiving the nck signal), the slower the PFET turn “on” time would be, the time duration for a clock to Q output falling edge would correspondingly be slower. Thus, while there would be a comparatively “fast” clock to Q rising edge time, there would be a “slow” clock to Q falling edge time. Advantageously, the inventive implementation as shown in FIG. 2C would resolve such a scenario, and would provide fast and balanced rising and falling edge delays of the clock to Q time, such that both delay times would be “equalized”.

Referring to FIG. 2D, a circuit diagram of an example dual latch (i.e., “master-slave” latch, flip-flop, circuit) 295 is shown. As illustrated, the example circuit 295 may be a dual tristate multiplexer slave latch implementation. In certain implementations, the circuit 295 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. In various implementations, the second latch 220 in FIG. 2D can correspond to the latch 100 and the second latch 220 of FIGS. 1A and 2A.

As illustrated, the circuit 295 (in FIG. 2D) can include the same elements and would be configured for the same operations as the circuit 200 (in FIG. 2A). However, the circuit 295 differs from the circuit 200 in that circuitry of the multiplexer 260 in FIG. 2A is replaced by first and second tri-state multiplexers 281, 282 in FIG. 2D. Specifically, the inverter H-17 226 and pass gate H-18 227 of the drive path circuitry 240 and the inverter J-20 229 and pass gate J-19 228 of the storage loop circuitry 250 in FIG. 2A are replaced with a tri-state multiplexer 281 in the drive path circuitry 240 and a tri-state multiplexer 282 in the storage loop circuitry 250.

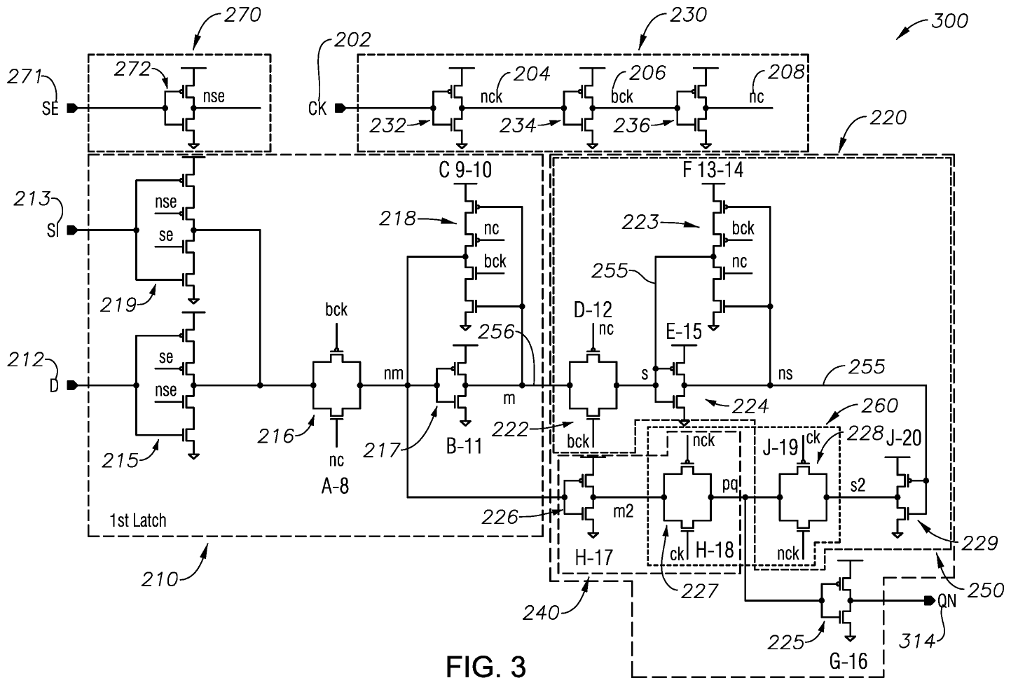

Referring to FIG. 3, a circuit diagram of an example dual latch (i.e., “master-slave” latch, flip-flop, circuit) 300 is shown. As illustrated, the example circuit 300 may be a scan-enable three serial-clock inverter flip-flop implementation. In certain implementations, the circuit 300 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. As may be appreciated, in certain implementations, the second latch 220 can correspond to the latch 100 of FIG. 1A.

As illustrated, while the circuit 300 (in FIG. 3) can include the same elements and would be configured for the same operations as the circuit 200 (in FIG. 2A), the specific circuit design provides for a different routing and wiring for inverter E-15 224 and the inverter H-17 226. Notably, with reference to the inverter E-15 224 in the storage loop circuitry 250, the gates of the PFET and NFET of the inverter E-15 224 may be coupled to a node between a drain of one of the PFETs and a drain of one of the NFETs of the tristate inverter F13-14 223. Also, with reference to the inverter H-17 226 in the drive loop circuitry 240, a node coupling both the NFET and PFET gates of the inverter H-17 226 may be coupled to a node between a drain of one of the PFETs and a drain of one of the NFETs of the tristate inverter C9-10 218, as well as a node coupled to the gates of inverter B-11 217. In addition, while there are no logic distinctions in comparison to FIG. 2A, in FIG. 3 the output signal would be an inverted output polarity, QN (i.e., /Q) 314.

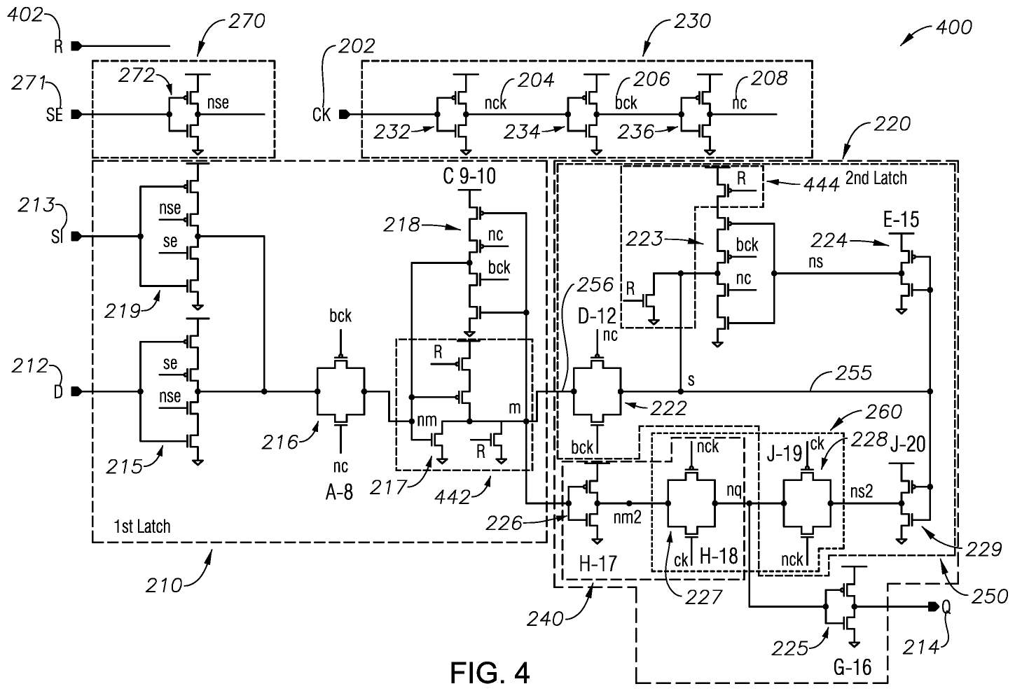

Referring to FIG. 4, a circuit diagram of an example dual latch (i.e., “master-slave” latch, flip-flop, circuit) 400 is shown. As illustrated, the example circuit 400 may be a scan-enable three serial-clock inverter flip-flop implementation. In certain implementations, the circuit 400 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. As may be appreciated, in certain implementations, the second latch 220 can correspond to the latch 100 of FIG. 1A.

As illustrated, while the circuit 400 (in FIG. 4) can include substantially the same elements (with the exception of inverter B-11 217) and would be configured for the substantially the same operations as the circuit 200 (in FIG. 2A), the circuit 400 provides additional logic gates (replacing the inverter B-11 217) for reset operations (upon receiving a reset signal (R) 402). For example, in FIG. 4, the circuit 400 includes a NOR gate 442 (including two PFET devices coupled in series, and two NFET devices coupled in parallel, where one PFET device and one NFET device are configured to receive the reset signal (R) 402) in the first latch 210, as well as logic 444 (including an NFET and a PFET that both receive the reset signal (R) 402) in the second latch 220. Hence, with the additional circuitry, the NOR gate 442 of the first latch 210 can be configured to perform a reset operation of the circuit 400. Moreover, as an advantage, in operation, a circuit operation (e.g., a delay of the circuit operation) of the drive path circuitry 240 would be distinct from the NOR gate circuitry configured to perform the reset operation. Accordingly, the C2Q delay benefit realized due to the inventive and “unburdened” drive path circuitry 240 would be unaffected by the NOR gate circuitry.

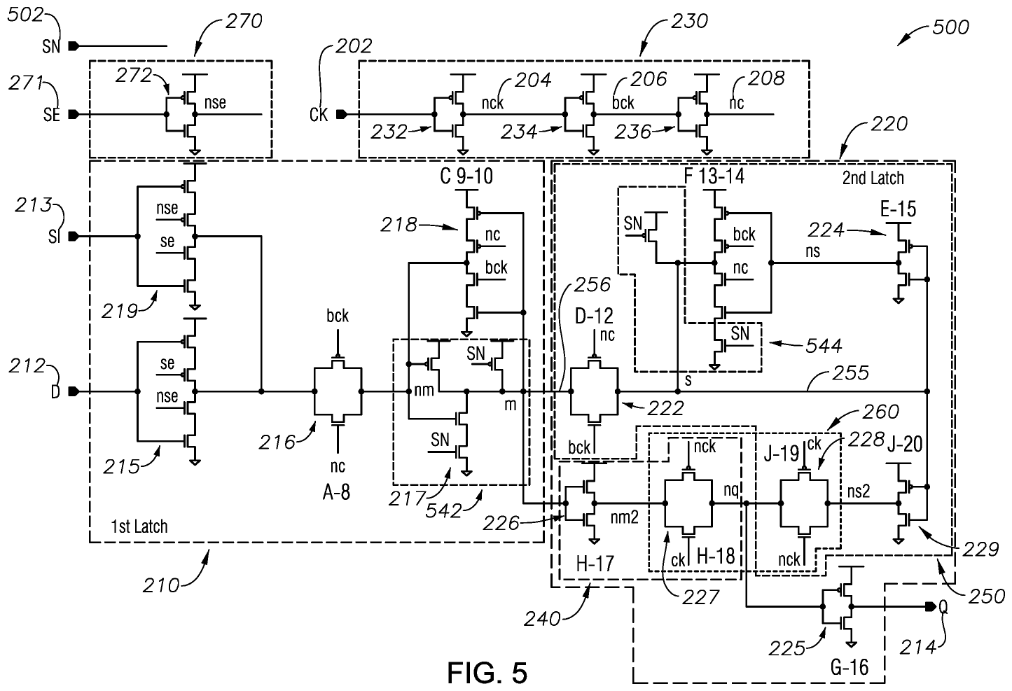

Referring to FIG. 5, a circuit diagram of an example dual latch (i.e., “master-slave” latch, flip-flop, circuit) 500 is shown. As illustrated, the example circuit 500 may be a scan-enable three serial-clock inverter flip-flop implementation. In certain implementations, the circuit 500 can include a first latch 210 (i.e., a master latch) and a second latch 220 (i.e., a slave latch), clock construction (i.e., clock-restructuring) circuitry 230, and scan-enable (SE) circuitry 270. Further, the slave latch 220 may include drive path circuitry 240 and storage loop circuitry 250, where certain portions of the each of the drive path circuitry 240 and the storage loop circuitry 250 may be configured as a multiplexer 260. As may be appreciated, in certain implementations, the second latch 220 can correspond to the latch 100 of FIG. 1A.

As illustrated, while the circuit 500 (in FIG. 5) can include substantially the same elements (with the exception of inverter B-11 217) and would be configured for substantially the operations as the circuit 200 (in FIG. 2A), the circuit 500 provides additional logic gates for (replacing the inverter B-11 217) for set operations (upon receiving a set signal (SN) 502). For example, in FIG. 5, the circuit 500 includes a NAND gate 542 (including two PFET devices coupled in parallel, and two NFET device coupled in series, where one PFET device and one NFET device are configured to receive the set signal (SN) 502) in the first latch 210, as well as logic 544 (including an NFET and a PFET both configured to receive the set signal (SN) 502 in the second latch 220. Hence, with the additional circuitry, the NAND gate 442 of the first latch 210 can be configured to perform a set operation of the circuit 500. Moreover, as an advantage, in operation, a circuit operation (e.g., a delay of the circuit operation) of the drive path circuitry 240 would be distinct from the NAND gate circuitry configured to perform the reset operation. Accordingly, the C2Q delay benefit realized due to the inventive and “unburdened” drive path circuitry 240 would be unaffected by the NAND gate circuitry.

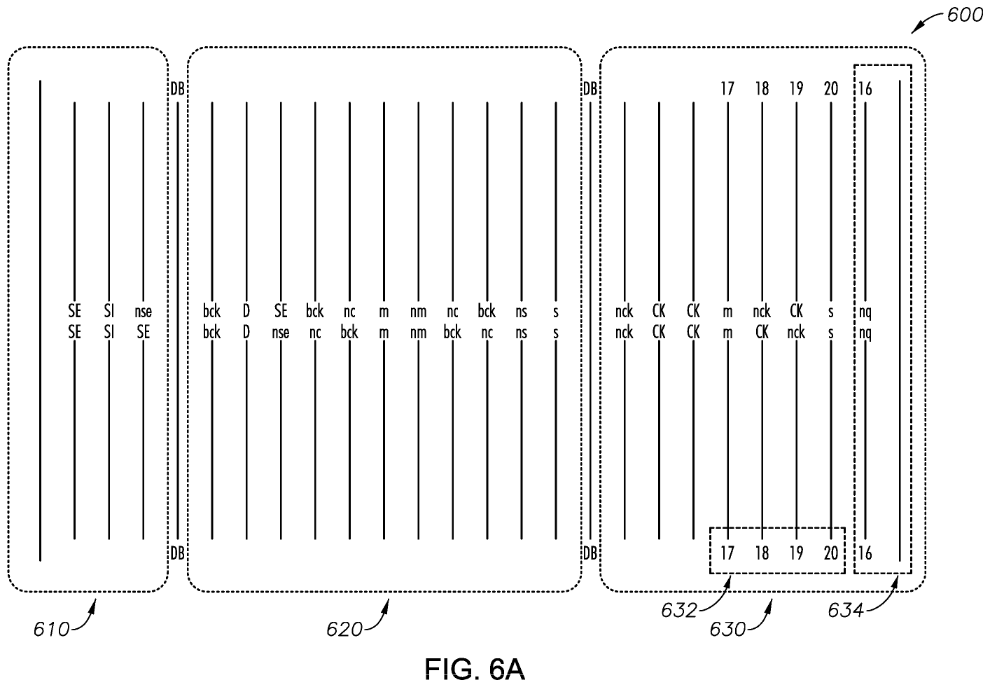

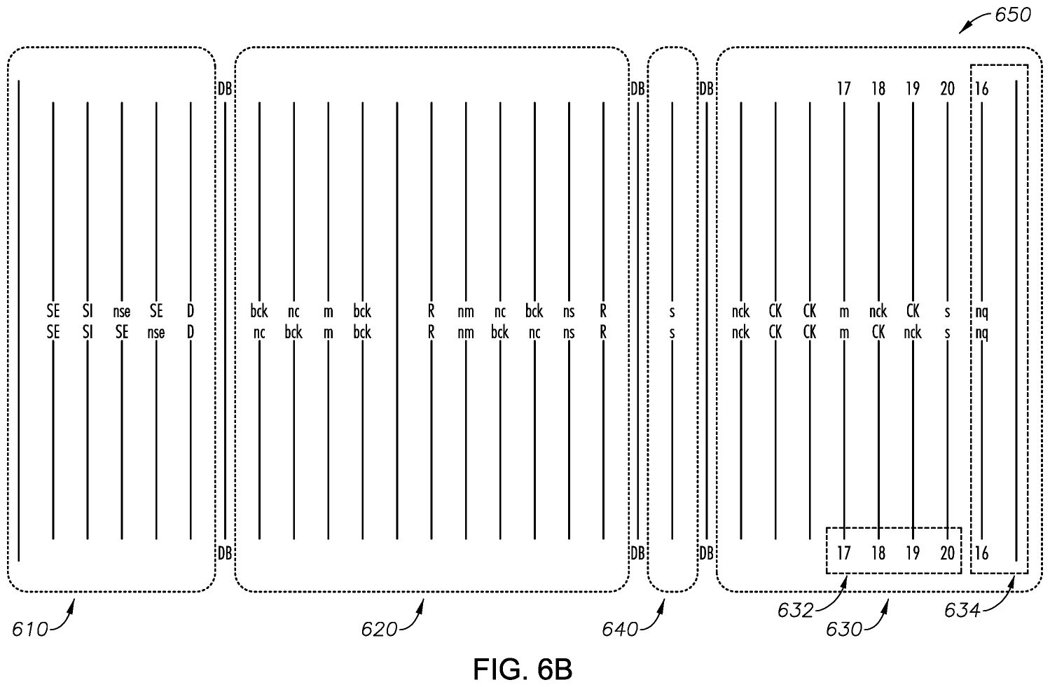

Referring to FIG. 6A, a layout floorplan 600 is shown. As illustrated, the floorplan comprises three distinct groupings (i.e., layout regions), separated by two diffusion breaks (DB) (i.e., separators in silicon), namely: first group (e.g., SE/SI) 610; middle group 620, and output group 630. In FIG. 6A, in certain implementations, one or more of the: clock signal (e.g., ck), a first delayed version of the clock signal (e.g., nck), the multiplexer and an output buffer are confined within (“bundled”) in the output group grouping of the PCB floor plan. Advantageously, by doing so, all of the “critical” signals (e.g., that are transmitted in the clock input-to-Q output circuit path) can be isolated in this region. Notably, pins 17-20 632 correspond to the transistor grouping of the multiplexer, H-17, H-18, J-19, and J-20. Moreover, as shown, pin 16 corresponds to output buffer generating output signal Q 214.

Referring to FIG. 6B, a layout floorplan 650 is shown. As illustrated, the floorplan comprises three distinct groupings (i.e., layout regions), separated by two diffusion breaks (DB) (i.e., separators in silicon), namely: first group (e.g., SE/SI) 610; a second group 620, a third group 640, and output group 630. The floorplan 650 in FIG. 6B expands on the floorplan 600 in FIG. 6A to include the additional reset operation logic. As may be appreciated, similar to the output group 630 in FIG. 6A, the output group 630 in FIG. 6B is exactly the same. The distinction between FIGS. 6A and 6B is seen in groupings distinct from the output group 630. Hence, any signals that arrive into the output group 630 would already be stabilized by the time the clock transitions from a “0” to a “1” (and hence, the C2Q delay would be unaffected by additional logic).

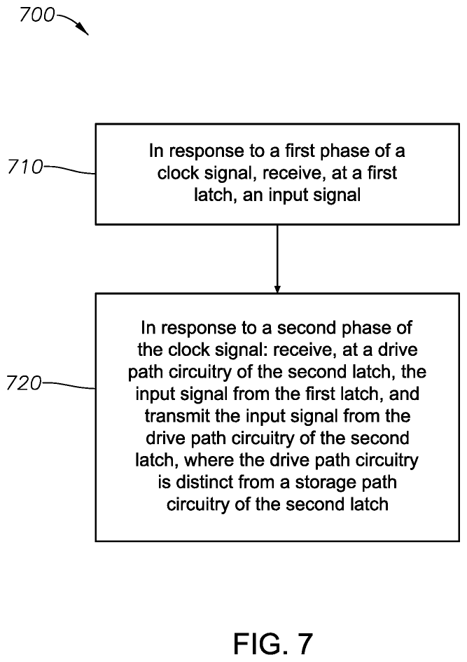

Referring to FIG. 7, a flowchart of an example operational method 700 (i.e., procedure) is shown. Advantageously, in various implementations, the method 700 is configured to: “unburden” and “streamline” a critical path (e.g., remove parasitic load from the critical path) and improve clock-to-Q output delay (e.g., by separate loading). The method 700 may be implemented with reference to circuit implementations as shown in, for example, FIGS. 1A-2A, 2A, 2B, 2C, 2D, 3, 4, 5, and 6A-6B.

At block 710, the method includes: in response to a first phase of a clock signal, an input signal is received at a first latch. For instance, with reference to various implementations as described in FIGS. 1A-6B, in response to a first phase of a clock signal (e.g., a first clock phase of a clock signal 202, e.g., when CK=0), an input signal (e.g., D input 212) can be received at (e.g., storage loop circuitry C9-10 218 and B-11 217) of a first latch (e.g., first latch 210).

At block 720, the method includes: in response to a second phase of the clock signal, the input signal (e.g., D input 212) can be received at a drive path circuitry of the second latch from a feedback loop circuitry of the first latch; and the input signal can be transmitted from the drive path circuitry of the slave latch, where the drive path circuitry is distinct from a storage path circuitry. For instance, with reference to various implementations as described in FIGS. 1A-6B, in response to a second phase of the clock signal (e.g., a second clock phase of a clock signal 202, e.g., CK=1, nck=0), the input signal (e.g., D input 212) can be received at a drive path circuitry 240 of the second latch 220 from a storage loop circuitry (e.g., tristate inverter C9-10 218 and inverter B-11 217) of the first latch; and the input signal (e.g., D input 213) can be transmitted to the drive path circuitry 240 of the slave latch 220 (e.g., to a Q output 214 or QN output 314), where the drive path circuitry 240 is distinct from a storage path circuitry 250.

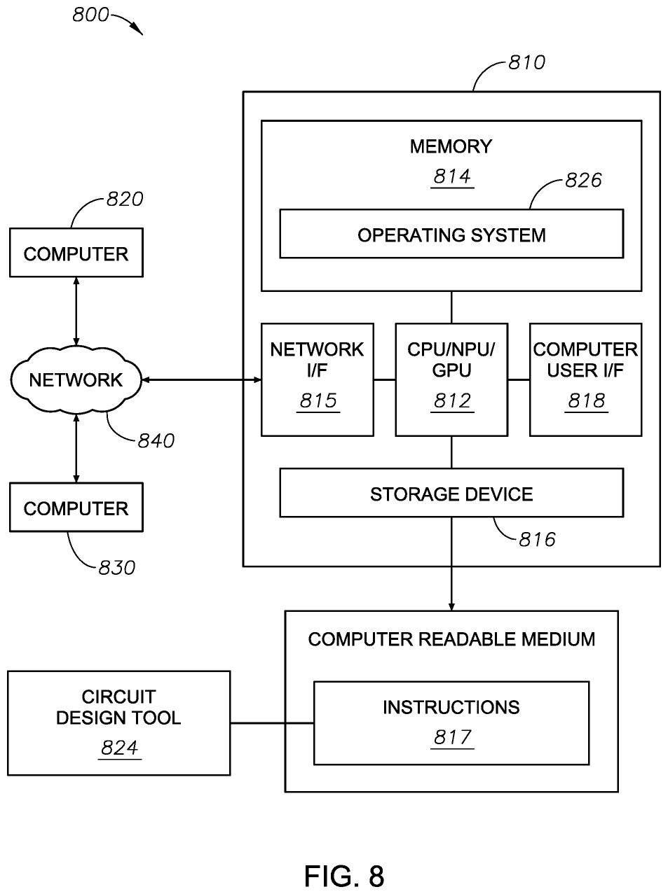

Also, according to other aspects of the operational methods, an output may be generated based on the operational dispositions. For example, with reference to various implementations as described in FIGS. 1A-6B, an output (i.e., a circuit design) (e.g., a memory architecture, multi-threshold offerings for memory compilers) may be generated based on various circuit element positionings. In some implementations, the circuit design tool 824 (as described with reference to FIG. 8) may allow users to input certain values, and generate a specific circuit design.

FIG. 8 illustrates example hardware components in the computer system 800 that may be used to provide optimized latch and flip-flop circuit designs, and integrate operations thereof. In certain implementations, the example computer system 800 (e.g., networked computer system and/or server) may include circuit design tool 824 and execute software based on the procedure as described with reference to the method 700 in FIG. 7. In certain implementations, the circuit design tool 824 may be included as a feature of circuit design program.

The circuit design tool 824 may provide generated computer-aided physical layout designs. The procedure 800 may be stored as program code as instructions 817 in the computer readable medium of the storage device 816 (or alternatively, in memory 814) that may be executed by the computer 810, or networked computers 820, 830, other networked electronic devices (not shown) or a combination thereof. In certain implementations, each of the computers 810, 820, 830 may be any type of computer, computer system, or other programmable electronic device. Further, each of the computers 810, 820, 830 may be implemented using one or more networked computers, e.g., in a cluster or other distributed computing system.

In certain implementations, the system 800 may be used with semiconductor integrated circuit (IC) designs that contain all standard cells, all blocks or a mixture of standard cells and blocks. In a particular example implementation, the system 800 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 800 may be stored in one or more of memory 814 or storage devices 816 of computer 810 or in networked computers 820, 820.

In one implementation, the computer 800 includes a central processing unit (CPU) 812 having at least one hardware-based processor coupled to a memory 814. The memory 814 may represent random access memory (RAM) devices of main storage of the computer 810, supplemental levels of memory (e.g., cache memories, non-volatile or backup memories (e.g., programmable or flash memories)), read-only memories, or combinations thereof. In addition to the memory 814, the computer system 800 may include other memory located elsewhere in the computer 810, such as cache memory in the CPU 812, as well as any storage capacity used as a virtual memory (e.g., as stored on a storage device 816 or on another computer coupled to the computer 810).

The computer 810 may further be configured to communicate information externally. To interface with a user or operator (e.g., a circuit design engineer), the computer 810 may include a user interface (I/F) 818 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 810 may include a network interface (I/F) 815 which may be coupled to one or more networks 840 (e.g., a wireless network) to enable communication of information with other computers and electronic devices. The computer 860 may include analog and/or digital interfaces between the CPU 812 and each of the components 814, 815, 816, and 818. Further, other non-limiting hardware environments may be used within the context of example implementations.

The computer 810 may operate under the control of an operating system 826 and may execute or otherwise rely upon various computer software applications, components, programs, objects, modules, data structures, etc. (such as the programs associated with the procedure 700 and the method 700 and related software). The operating system 828 may be stored in the memory 814. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 826 in the example of FIG. 8 is shown in the memory 814, but components of the aforementioned software may also, or in addition, be stored at non-volatile memory (e.g., on storage device 816 (data storage) and/or the non-volatile memory (not shown). Moreover, various applications, components, programs, objects, modules, etc. may also execute on one or more processors in another computer coupled to the computer 810 via the network 840 (e.g., in a distributed or client-server computing environment) where the processing to implement the functions of a computer program may be allocated to multiple computers 820, 830 over the network 840.

In example implementations, circuit diagrams have been provided in FIGS. 1A-6B, whose redundant description has not been duplicated in the related description of analogous circuit macro diagrams. It is expressly incorporated that the same diagrams with identical symbols and/or reference numerals are included in each of embodiments based on its corresponding figure(s).

Although one or more of FIGS. 1-8 may illustrate systems, apparatuses, or methods according to the teachings of the disclosure, the disclosure is not limited to these illustrated systems, apparatuses, or methods. One or more functions or components of any of FIGS. 1-8 as illustrated or described herein may be combined with one or more other portions of another of FIGS. 1-8. Accordingly, no single implementation described herein should be construed as limiting and implementations of the disclosure may be suitably combined without departing from the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 814, the storage device 816, or both, may include tangible, non-transitory computer-readable media, or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus, or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
a latch comprising:
a drive path circuitry configured to transmit an output signal; and
a storage loop circuitry configured to retain the output signal.

2. The circuit of claim 1, wherein:
a portion of each of the drive path circuitry and the storage loop circuitry is configured as a multiplexer;
a clock signal is a selector of the multiplexer;
the multiplexer is configured to select between a drive path signal and a storage loop signal and transmit a multiplexed output signal; and
the drive path signal corresponds to the output signal.

3. The circuit of claim 2, wherein the portion comprises a pass gate.

4. The circuit of claim 2, further comprising:
clock restructuring circuitry comprising:
first and second clock gates configured to generate first and second clock inverter signals, wherein either the clock signal or the first clock inverter signal is configured as the selector.

5. The circuit of claim 4, wherein:
the first and second clock gates are serially coupled;
the first and second clock inverter signals comprise a different polarity; and
the clock signal and the second clock inverter signal comprise a same polarity.

6. The circuit of claim 4, wherein the clock restructuring circuitry comprises:
a third clock gate configured to the generate a third clock inverter signal, wherein:
the third clock gate is parallel coupled to the first and second clock gates;
the first and the third clock inverter signals comprise a same polarity; and
the third clock inverter signal is configured as the selector.

7. The circuit of claim 4, wherein the clock restructuring circuitry comprises:
a third clock gate configured to the generate a third clock inverter signal, wherein:
the third clock gate is serially coupled to the first and second clock gates; and
the first and the third clock inverter signals comprises a same polarity; and
the first clock inverter signal is configured as the selector.

8. The circuit of claim 1, wherein:
the storage loop circuitry comprises two pass gates;
the drive path circuitry comprises a sole pass gate; and
the sole pass gate of the drive path circuitry is configured to generate the output signal.

9. The circuit of claim 1, further comprising:
a master latch coupled to the latch, wherein the latch comprises a slave latch.

10. The circuit of claim 9, wherein the first and second latches comprises:
respective first and second storage nodes, wherein each of the first and second storage nodes comprises a respective feedback loop memory structure, and wherein:
the feedback loop memory structure comprises an inverter and a tri-state inverter; and
the drive path circuitry is distinct from the first and second storage nodes.

11. The circuit of claim 1, further comprising:
a master latch, wherein:
the latch comprises a slave latch; and
the slave latch comprises multiplexer circuitry configured to select between a first input signal and a second input signal.

12. The circuit of claim 11, wherein:
the multiplexer circuitry comprises a pass gate of storage loop circuitry and a pass gate of drive path circuitry;
the first input signal corresponds to a drive path signal of the drive path circuitry and the second input signal corresponds to a storage loop path signal of the storage path circuitry; and
the multiplexer circuitry is configured to transmit a multiplexed output signal.

13. The circuit of claim 12, wherein:
the pass gate of the storage loop circuitry and the pass gate of the drive path circuitry are configured to operate out-of-phase; and
the out-of-phase operation comprises opposing activation of the storage loop circuitry and the drive path circuitry.

14. The circuit of claim 11, wherein:
the first latch comprises either a logic gate to perform a set operation or a logic gate to perform a reset operation of the circuit;
the logic gate comprises a NOR gate when the first latch is configured to perform the reset operation;
the logic gate comprises a NAND gate when the first latch is configured to perform the set operation; and
the drive path circuitry is distinct from the logic gate.

15. The circuit of claim 11, wherein:
one or more of: a clock signal, a first clock inverter signal, the multiplexer circuitry, and an output buffer are confined within a first layout region of a floor plan; and
the first layout region is separated from a second layout region by a diffusion break.

16. The circuit of claim 11, further comprising:
clock restructuring circuitry comprising:
first, second, and third clock gates configured to generate first, second, and third clock inverter signals, wherein either:
the first, second, and third clock gates are serially coupled; or
the first and second clock gates are parallel coupled to the third clock gate.

17. A method comprising:
in response to a first occurrence of a first phase of a clock signal,
receiving, at a first latch, an input signal; and
in response to a first occurrence of a second phase of the clock signal:
receiving, at a drive path circuitry of the second latch, the input signal from the first latch, and
transmitting the input signal from the drive path circuitry of the second latch, wherein the drive path circuitry is distinct from a storage path circuitry of the second latch.

18. The method of claim 17, further comprising:
in response to the first occurrence of the first phase of the clock signal,
storing, at the first latch, the input signal; and
storing, at the storage path circuitry of the second latch, a stored input signal.

19. The method of claim 17, further comprising:
in response to a second occurrence of the first phase of the clock signal,
storing, at the storage path circuitry of the second latch, the input signal.

20. A circuit comprising:
clock restructuring circuitry configured to generate respective first, second, and third clock inverter signals;
a first latch configured to transmit a drive path signal;
a second latch configured to transmit a storage loop signal; and
a multiplexer, wherein:
one or more transistor devices of the first and the second latches are activated by the second or the third inverter signals;
the multiplexer is configured to select between the drive path signal and the storage loop signal based on a selector signal; and
the selector signal is either a clock signal or the first clock inverter signal.
